(19) United States
(12) Patent Application Publication
(10) Pub. No.: US 2025/0089526 A1
(43) Pub. Date: Mar. 13, 2025

(54) DISPLAY PANELS AND DISPLAY APPARATUSES

(71) Applicant: BOE Technology Group Co., Ltd., Beijing (CN)

(72) Inventors: Renrong GAI, Beijing (CN); Tao WANG, Beijing (CN); Yue CUI, Beijing (CN); Tao SUN, Beijing (CN); Rui HOU, Beijing (CN)

(21) Appl. No.: 18/031,758

(22) PCT Filed: May 31, 2022
(86) PCT No.: PCT/CN2022/096471

§ 371 Date: Apr. 13, 2023

(51) Int. Cl. H10K 59/80; H10K 59/122

(52) U.S. Cl. CPC H10K 59/873; H10K 59/122; H10K 59/8722

(57) ABSTRACT

The present disclosure relates to the field of display technology, and provides a display panel and a display apparatus. The display panel includes a display area and a frame area surrounding the display area. The display panel includes: a base substrate and a cover plate opposite to each other; one or more convex ribs on at least one of the base substrate and the cover plate, where each convex rib of at least some of the convex ribs includes a plurality of rib segments connected sequentially along an extension trajectory of the convex rib, and an angle is formed between adjacent two of the rib segments; and an encapsulation structure between the base substrate and the cover plate and covering the convex ribs. The present disclosure is capable of improving an encapsulation effect.

### CROSS-REFERENCE TO RELATED APPLICATIONS

This application is the U.S. national phase of PCT Application No. PCT/CN2022/096471 filed on May 31, 2022, the disclosure of which is incorporated herein by reference in its entirety.

### TECHNICAL FIELD

The present invention relates to the field of display technology, and in particular to a display panel and a display apparatus.

### BACKGROUND

With the improvement of living standards, display panels have attracted more and more attention. Display panels include OLED display panels, and the like. OLED display panels have a series of advantages such as all-solid-state structure, self-luminescence, fast response, high brightness, full-view, and flexible display. However, the existing display panels have poor encapsulation effects.

### SUMMARY

An objective of the present disclosure is to provide a display panel and a display apparatus capable of improving an encapsulation effect.

According to an aspect of the present disclosure, there is provided a display panel including a display area and a frame area surrounding the display area, the display panel including:
a base substrate and a cover plate opposite to each other;
one or more convex ribs on at least one of the base substrate and the cover plate, where each convex rib of at least some of the convex ribs includes a plurality of rib segments connected sequentially along an extension trajectory of the convex rib, and an angle is formed between adjacent two of the rib segments; and
an encapsulation structure between the base substrate and the cover plate and covering the convex ribs.

Further, the plurality of rib segments include at least a first rib segment, a second rib segment, and a third rib segment connected sequentially, where an angle is formed between the first rib segment and the second rib segment, and an angle is formed between the third rib segment and the second rib segment, and an end of the first rib segment away from the second rib segment and an end of the third rib segment away from the second rib segment are on a same side in a width direction of the second rib segment.

Further, the angle formed between the adjacent two of the rib segments is an obtuse angle.

Further, a plurality of convex rib groups are provided on at least one of the base substrate and the cover plate and are distributed at intervals, each of the convex rib groups including one or more of the convex ribs.

Further, multiple of the convex rib groups are in the frame area, and are distributed at intervals along a periphery of the display area.

Further, the frame area is in a ring shape and includes at least one corner portion, and a density of the convex ribs at the corner portion of the frame area is greater than that of the convex ribs at other portions of the frame area.

Further, the plurality of rib segments include at least a first rib segment, a second rib segment, and a third rib segment connected sequentially, where an angle is formed between the first rib segment and the second rib segment, and an angle is formed between the third rib segment and the second rib segment, and an end of the first rib segment away from the second rib segment and an end of the third rib segment away from the second rib segment are on a same side in a width direction of the second rib segment; and
the convex ribs include one or more first convex ribs and one or more second convex ribs, and for each of the first convex ribs, an end of the first rib segment away from the second rib segment is on a side of the second rib segment facing the display area, and for each of the second convex ribs, an end of the first rib segment away from the second rib segment is on a side of the second rib segment facing away from the display area.

Further, multiple of the convex rib groups are provided on a portion of the base substrate located in the frame area and on a portion of the cover plate located in the frame area; and
the convex ribs in one or more convex rib groups provided on the base substrate and located in the frame area are the first convex ribs, and the convex ribs in one or more convex rib groups provided on the cover plate and located in the frame area are the second convex ribs, or the convex ribs in the one or more convex rib groups provided on the base substrate and located in the frame area are the second convex ribs, and the convex ribs in the one or more convex rib groups provided on the cover plate and located in the frame area are the first convex ribs.

Further, multiple of the convex rib groups are provided on a portion of the base substrate located in the frame area, and are distributed at intervals along a periphery of the display area, and among adjacent two of the multiple of the convex rib groups, the convex ribs in one convex rib group are the first convex ribs, and the convex ribs in the other convex rib group are the second convex ribs; and/or
multiple of the convex rib groups are provided on a portion of the cover plate located in the frame area, and are distributed at intervals along the periphery of the display area, and among adjacent two of the multiple of the convex rib groups, the convex ribs in one convex rib group are the first convex ribs, and the convex ribs in the other convex rib group are the second convex ribs.

Further, the encapsulation structure includes a sealant provided in the frame area and bonded between the base substrate and the cover plate; and
one of the convex ribs is provided in the frame area and is covered by the sealant, or multiple of the convex ribs are provided in the frame area and are at least partially covered by the sealant.

Further, the base substrate includes a base and a light-emitting unit on the base, and the encapsulation structure includes an encapsulation layer covering the light-emitting unit; and

one of the convex ribs is provided on a portion of the base substrate located in the frame area and is covered by the encapsulation layer, or multiple of the convex ribs are provided on the portion of the base substrate located in the frame area and are at least partially covered by the encapsulation layer.

Further, multiple of the convex ribs are provided on the portion of the base substrate located in the frame area, with a part of the multiple of the convex ribs being covered by the encapsulation layer and another part of the multiple of the convex ribs being located outside the encapsulation layer; and the encapsulation structure further includes a sealant which is bonded between the base substrate and the cover plate and covers the convex ribs located outside the encapsulation layer.

Further, the encapsulation structure includes an encapsulation layer, and the base substrate includes a base, a light-emitting unit, and a barrier dam; the light-emitting unit is provided on the base, and the encapsulation layer covers the light-emitting unit; the barrier dam is provided on the base and located in the frame area, and the barrier dam is configured to block a portion of the encapsulation layer; and one or more of the convex ribs are provided in the frame area on a side of the barrier dam away from the display area.

Further, the convex rib includes a first portion and a second portion in a thickness direction of the base substrate, and a size of the first portion is greater than that of the second portion in a width direction of the convex rib;
in the case that the convex rib is provided on the base substrate, the first portion is located on a side of the second portion away from the base substrate; and
in the case that the convex rib is provided on the cover plate, the first portion is located on a side of the second portion away from the cover plate.

Further, an etch rate of a material of the first portion is less than that of a material of the second portion.

Further, one or more of the convex ribs are provided on a portion of the base substrate located in the frame area, and the base substrate includes:
a base;
a driving transistor on the base;
a planarization layer on a side of the driving transistor facing away from the base, the second portions of the convex ribs in the frame area being on a surface of the planarization layer facing away from the base; and
a pixel definition layer covering the planarization layer and the second portions, an area of the pixel definition layer covering the second portions forming the first portions.

Further, one or more of the convex ribs are provided on a portion of the base substrate located in the frame area, and the base substrate includes:
a base;
a driving transistor on the base; and
a planarization layer on a side of the driving transistor facing away from the base, a portion of the planarization layer forming the second portions of the convex ribs in the frame area.

Further, one or more of the convex ribs are provided on a portion of the base substrate located in the display area, and the base substrate includes:
a base;
a pixel definition layer on a side of the base and with a pixel opening; and
a light-emitting unit in the pixel opening,
where a plurality of strip-shaped grooves are provided in a surface of the pixel definition layer facing the cover plate and are distributed at intervals, and a portion of the pixel definition layer located between adjacent two of the strip-shaped grooves forms the second portion.

Further, one or more of the convex ribs are provided in the display area, and the base substrate includes:
a base;
a pixel definition layer on a side of the base and with a pixel opening; and
a light-emitting unit in the pixel opening,
where orthographic projections of the convex ribs in the display area on the base are within an area of an orthographic projection of the pixel definition layer on the base.

Further, the extension trajectory of the convex rib is arcuate and surrounds at least one pixel opening.

Further, the pixel opening is polygonal, and the extension trajectory of the convex rib surrounds a vertex of the pixel opening.

Further, a material of the convex rib includes a negative photoresist.

Further, the plurality of rib segments include at least a first rib segment, a second rib segment, and a third rib segment connected sequentially, where an angle is formed between the first rib segment and the second rib segment, and an angle is formed between the third rib segment and the second rib segment, and an end of the first rib segment away from the second rib segment and an end of the third rib segment away from the second rib segment are on a same side in a width direction of the second rib segment;
multiple of the convex ribs are provided in the display area, with the second rib segment of one convex rib being parallel to the second rib segment of another convex rib; and
multiple of the convex rib groups are provided in the display area, with two convex ribs of which the second rib segments are parallel to each other being in a same convex rib group, or two convex ribs of which the second rib segments are parallel to each other being in different convex rib groups.

Further, two of the convex rib groups are provided on a periphery of the pixel opening, and the two convex rib groups are provided on two sides of the pixel opening, with the second rib segments of the convex ribs in one convex rib group being parallel to the second rib segments of the convex ribs in the other convex rib group.

Further, the plurality of rib segments include at least a first rib segment, a second rib segment, and a third rib segment connected sequentially, where an angle is formed between the first rib segment and the second rib segment, and an angle is formed between the third rib in segment and the second rib segment, and an end of the first rib segment away from the second rib segment and an end of the third rib segment away from the second rib segment are on a same side in a width direction of the second rib segment; and
multiple of the convex ribs are provided in the display area, with the second rib segment of one convex rib being perpendicular to the second rib segment of another convex rib, and two convex ribs of which the second rib segments are perpendicular to each other are in different convex rib groups.

Further, the convex rib group includes multiple of the convex ribs distributed at intervals, with a trench being formed between adjacent two of the multiple of the convex ribs.

Further, one or more of the convex rib groups are provided on a portion of the base substrate located in the display area; the encapsulation structure includes an encapsulation layer, the encapsulation layer including a first inorganic encapsulation layer and a second inorganic encapsulation layer opposite to each other, and an organic encapsulation layer coated between the first inorganic encapsulation layer and the second inorganic encapsulation layer; and the second inorganic encapsulation layer is on a side of the first inorganic encapsulation layer facing the cover plate; and
the first inorganic encapsulation layer covers the convex ribs, and a ratio of a distance between two adjacent convex ribs to a thickness of the first inorganic encapsulation layer is greater than or equal to 2.

Further, the convex ribs are provided on the base substrate and the cover plate, and orthographic projections of the convex ribs on the base substrate on the cover plate and the convex ribs on the cover plate are arranged at intervals.

According to an aspect of the present disclosure, there is provided a display apparatus including the display panel.

With the display panel and the display apparatus according to embodiments of the present disclosure, the encapsulation structure may be provided between the base substrate and the cover plate and cover the convex ribs. In the case that the convex ribs are provided on the base substrate, a bonding area and thus a bonding force between the encapsulation structure and the base substrate can be increased. In the case that the convex ribs are provided on the cover plate, a bonding area and thus a bonding force between the encapsulation structure and the cover plate can be increased. Therefore, with the present disclosure, the bonding force between the encapsulation structure and the cover plate or the base substrate can be increased, thereby improving the encapsulation effect.

### BRIEF DESCRIPTION OF THE DRAWINGS

FIG. 1 is a schematic diagram illustrating a display panel according to an embodiment of the present disclosure.

FIGS. 2A to 2C are schematic diagrams illustrating distribution of convex ribs and an encapsulation structure according to embodiments of the present disclosure.

FIG. 3 is a schematic diagram illustrating a convex rib according to an embodiment of the present disclosure.

FIG. 4 is a schematic diagram illustrating a convex rib group according to an embodiment of the present disclosure.

FIGS. 5 to 7 are schematic cross-sectional views illustrating a convex rib according to embodiments of the present disclosure.

FIG. 8 is a schematic diagram illustrating a convex rib and an encapsulation layer according to an embodiment of the present disclosure.

FIGS. 9 to 11 are schematic diagrams illustrating a base substrate according to embodiments of the present disclosure.

FIGS. 12 to 15 are schematic diagrams illustrating a cover plate according to embodiments of the present disclosure.

FIGS. 16 to 27 are schematic diagrams illustrating pixel openings and convex ribs according to embodiments of the present disclosure.

FIG. 28 is a schematic diagram illustrating a pixel definition layer according to an embodiment of the present disclosure.

FIG. 29 is a schematic diagram illustrating an encapsulation structure and convex ribs according to an embodiment of the present disclosure.

Description of reference numerals: 1. base; 2. thin-film transistor; 21. active layer; 22. gate insulating layer; 23. gate electrode; 24. interlayer insulating layer; 25. source electrode; 26. drain electrode; 3. first planarization layer; 4. conductive connecting line; 5. second planarization layer; 6. light-emitting unit; 61. anode; 62. light-emitting layer; 63. cathode; 7. pixel definition layer; 701. strip-shaped groove; 8. transfer line; 9. convex rib; 901. first rib segment; 902. second rib segment; 903. third rib segment; 904. first portion; 905. second portion; 906. third portion; 10. signal line; 11. barrier dam; 12. cover plate; 13. encapsulation layer; 14. sealant; 16. pixel opening; 1601. first opening; 1602. second opening; 1603. third opening; 100. display area; 1001. corner portion; 200. frame area; 300. convex rib group.

### DETAILED DESCRIPTION OF THE EMBODIMENTS

Reference will now be made in detail to exemplary embodiments, examples of which are illustrated in the accompanying drawings. When the following description refers to the drawings, like numerals in different drawings indicate like or similar elements, unless otherwise indicated. Embodiments described in the following exemplary embodiments are not intended to represent all embodiments consistent with the present invention. Rather, they are merely examples of apparatuses consistent with some aspects of the present invention as detailed in the appended claims.

Terms used in the present invention are for the purpose of describing particular embodiments only, and are not intended to limit the present invention. Unless otherwise defined, technical or scientific terms used in the present invention shall have their ordinary meanings as understood by those ordinary skilled in the art to which the present invention belongs. Words “first,” “second,” and the like used in the specification and claims of the present invention do not indicate any order, quantity, or importance, but are only used to distinguish between different components. Likewise, words “a” or “an” and the like do not indicate any limitation in quantity, but rather indicate the presence of at least one. “A plurality of” or “several” indicates two or more. Words “include” or “comprise” and the like are intended to mean that an element or item appearing before “include” or “comprise” encompasses elements or items listed after “include” or “comprise” and equivalents thereof, and are not intended to exclude other elements or items. Words “connect” or “couple” and the like are not limited to physical or mechanical connections, but may include electrical connections, whether direct or indirect. As used in the specification and the appended claims of the present invention, terms determined by “a,” “said,” and “the” in their singular forms are intended to include plural forms as well, unless clearly indicated otherwise in the context. It should also be understood that the term “and/or” as used herein refers to and includes any or all possible combinations of one or more of the associated listed items.

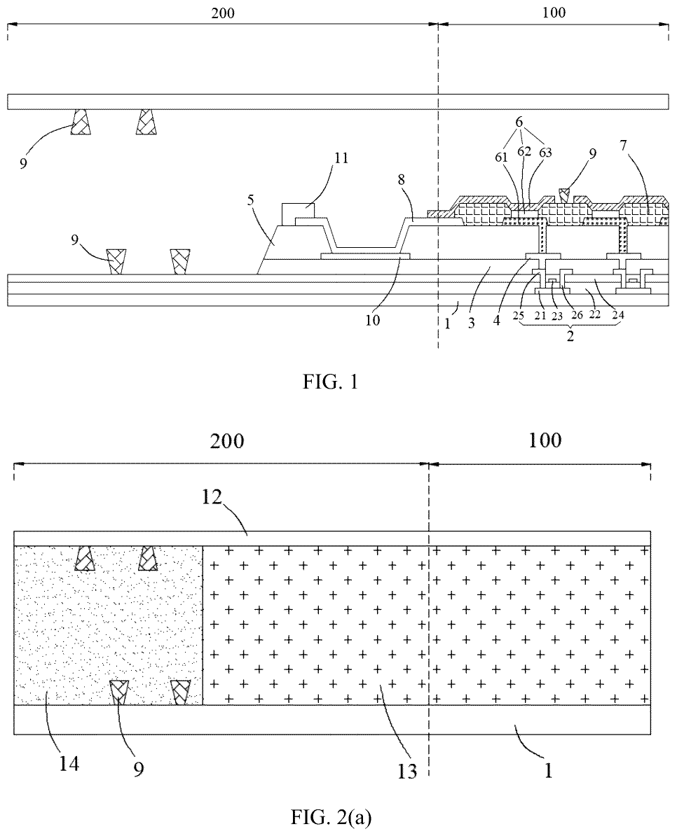

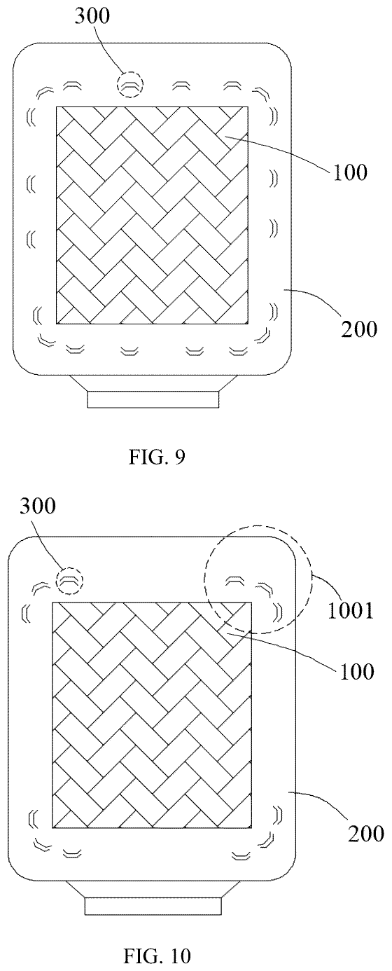

Embodiments of the present disclosure provide a display panel. As shown in FIG. 1 and FIG. 9, the display panel may include a display area 100 and a frame area 200. The display area 100 may be rectangular, circular, elliptical, square, etc. The frame area 200 surrounds the display area 100, that is, the frame area 200 is in a ring shape. The display panel may include a base substrate, a cover plate 12, a convex rib 9, and an encapsulation structure.

The base substrate and the cover plate 12 are disposed opposite to each other. The convex rib 9 is provided on at least one of the base substrate and the cover plate 12. The encapsulation structure may be provided between the base substrate and the cover plate 12, and may cover the convex rib 9. The display panel may include one or more convex ribs 9, where each convex rib of at least some of the convex ribs 9 includes a plurality of rib segments connected sequentially along an extension trajectory of the convex rib 9, with an angle formed between adjacent two of the rib segments.

With the display panel according to the embodiments of the present disclosure, the encapsulation structure may be disposed between the base substrate and the cover plate 12, and cover the convex ribs 9. In the case that the base substrate is provided with the convex ribs 9, a bonding area and thus a bonding force between the encapsulation structure and the base substrate can be increased. In the case that the cover plate 12 is provided with the convex ribs 9, a bonding area and thus a bonding force between the encapsulation structure and the cover plate 12 can be increased. Therefore, with the present disclosure, the bonding force between the encapsulation structure and the cover plate 12 or the base substrate can be increased, thereby improving the encapsulation effect.

Components of the display panel according to the embodiments of the present disclosure will be described in detail below.

As shown in FIG. 1, the base substrate may include a base 1. The base 1 may be a rigid base. The rigid base may include a glass base or a PMMA (polymethyl methacrylate) base. However, the base 1 may be a flexible base. The flexible base may include a PET (polyethylene terephthalate) base, a PEN (Polyethylene naphthalate two formic acid glycol ester) base, or a PI (polyimide) base.

As shown in FIG. 1, a driving transistor may be provided on the base 1. The driving transistor may be a thin-film transistor (TFT) 2, but the embodiments of the present disclosure are not limited thereto. The TFT 2 may be a top-gate TFT; however, the TFT 2 may also be a bottom-gate TFT. For example, in the case of a top-gate TFT, the TFT 2 may include an active layer 21, a gate insulating layer 22, a gate electrode 23, an interlayer insulating layer 24, a source electrode 25, and a drain electrode 26. The active layer 21 may be provided on the base 1. The gate insulating layer 22 may be provided on the base 1 and cover the active layer 21. The gate electrode 23 may be provided on a side of the gate insulating layer 22 away from the base 1. The interlayer insulating layer 24 may be provided on the gate insulating layer 22 and cover the gate electrode 23. The source electrode 25 and the drain electrode 26 may be provided on the interlayer insulating layer 24 and connected to the active layer 21 via vias passing through the interlayer insulating layer 24 and the gate insulating layer 22.

As shown in FIG. 1, the base substrate may further include a planarization layer and a conductive connecting line 4. The planarization layer may include a first planarization layer 3 and a second planarization layer 5. The first planarization layer 3 may cover the source electrode 25, the drain electrode 26, and the interlayer insulating layer 24. The conductive connecting line 4 may be provided on the first planarization layer 3 and electrically connected to the source electrode 25 or the drain electrode 26 of the TFT 2 via a via passing through the first planarization layer 3. The base substrate may further include a signal line 10. The signal line 10 may be provided on a surface of the first planarization layer 3 facing away from the base 1. The signal line 10 may be arranged in the same layer as the conductive connecting line 4. The signal line 10 may be electrically connected to a power signal terminal. The signal line 10 may be electrically connected to a VSS power signal terminal or a VDD power signal terminal. The second planarization layer 5 may cover the conductive connecting line 4 and the signal line 10.

As shown in FIG. 1, the base substrate may further include a light-emitting unit 6. The light-emitting unit 6 may include an anode 61, a light-emitting layer 62, and a cathode 63 arranged in a stack. The light-emitting layer 62 may be an organic electroluminescent layer or a quantum dot layer, but the present disclosure is not limited thereto. The display panel according to the present disclosure may further include a transfer line 8. The anode 61 and the transfer line 8 are arranged in the same layer, and both are provided on a side of the second planarization layer 5 facing away from the base 1. The anode 61 is electrically connected to the conductive connecting line 4 via a via passing through the second planarization layer 5, such that the anode 61 is electrically connected to the source electrode 25 or the drain electrode 26 of the TFT 2. The transfer line 8 is electrically connected to the signal line 10 via a via in the second planarization layer 5. The display panel according to the present disclosure may further include a pixel definition layer 7. The pixel definition layer 7 covers the second planarization layer 5, the anode 61, and the transfer line 8. The pixel definition layer 7 is provided with a pixel opening 16 exposing the anode 61. The pixel opening 16 may include a first opening 1601, a second opening 1602, and a third opening 1603. The light-emitting layer 62 of the light-emitting unit 6 is provided in the pixel opening 16. The light-emitting layer 62 for emitting blue light is provided in the first opening 1601, the light-emitting layer 62 for emitting green light is provided in the second opening 1602, and the light-emitting layer 62 for emitting red light is provided in the third opening 1603. The cathode 63 of the light-emitting unit 6 is provided on a side of the light-emitting layer 62 facing away from the base 1, and is electrically connected to the transfer line 8 via a via passing through the pixel definition layer 7.

As shown in FIG. 8, the encapsulation structure may include an encapsulation layer 13. The encapsulation layer 13 may cover the light-emitting unit 6. In an embodiment, the encapsulation layer 13 is made of an inorganic material. In another embodiment, the encapsulation layer 13 may include a first inorganic encapsulation layer, an organic encapsulation layer, and a second inorganic encapsulation layer. The first inorganic encapsulation layer and the second inorganic encapsulation layer are disposed opposite to each other, and the organic encapsulation layer is coated between the first inorganic encapsulation layer and the second inorganic encapsulation layer. In the present disclosure, it is found through tests that the smaller a thickness of the organic encapsulation layer is, the greater a vertical squeezing force that the encapsulation structure can withstand. For example, when the thickness of the organic encapsulation layer is 16 μm, the vertical squeezing force that the encapsulation structure can withstand is 32N; and when the thickness of the organic encapsulation layer is 12 μm, the vertical squeezing force that the encapsulation structure can withstand is 40N. In order to increase the vertical squeezing force that the encapsulation structure can withstand, the thickness of the organic encapsulation layer in the present disclosure is set as 6 μm to 12 μm, e.g., 6 μm, 7 μm, 9 μm, 10 μm, 12 μm, etc.

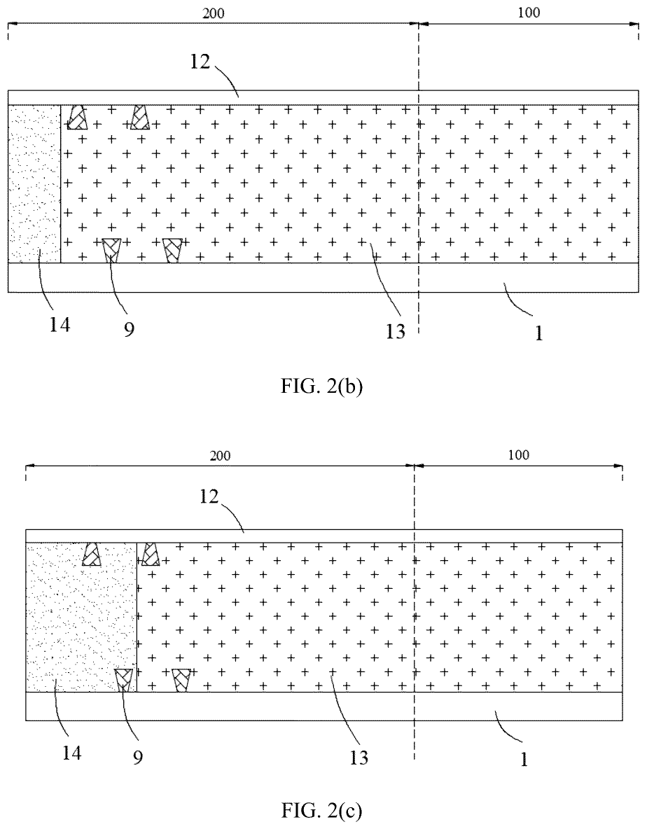

As shown in FIG. 1, the display panel may further include a barrier dam 11. The barrier dam 11 may be disposed on the base 1 and located in the frame area 200. The barrier dam 11 is configured to block a portion of the encapsulation layer 13. In particular, the first inorganic encapsulation layer may cover the barrier dam, the second inorganic encapsulation layer may cover an area of the first inorganic encapsulation layer corresponding to the barrier dam, and the barrier dam may block the organic encapsulation layer. As shown in FIG. 2A, the encapsulation structure may further include a sealant 14, which may be located outside the encapsulation layer 13 in a direction parallel to the base 1. The sealant 14 may be spaced apart from the encapsulation layer 13. The cover plate 12 is disposed opposite to the base substrate, and the cover plate 12 may be connected to the base substrate through the sealant 14 and the encapsulation layer 13.

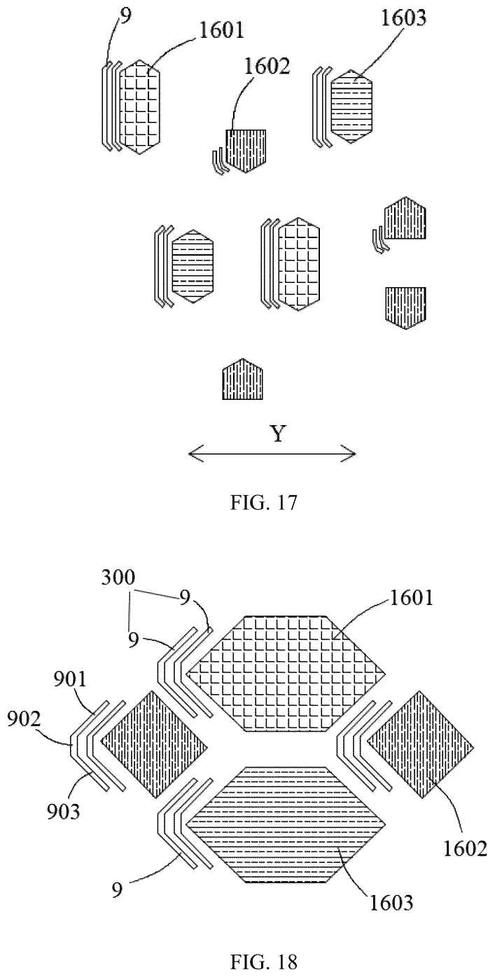

As shown in FIG. 1, the convex ribs 9 are provided on at least one of the base substrate and the cover plate 12. The convex ribs 9 may be provided only in the display area 100, or the convex ribs 9 may be provided only in the frame area 200, but the present disclosure is not limited thereto, and the convex ribs 9 may be provided in both the display area 100 and the frame area 200. The convex ribs 9 provided in the frame area 200 may be located on a side of the barrier dam 11 away from the display area 100. In an embodiment, as shown in FIG. 2A, one or more convex ribs 9 are provided in the frame area 200, and the sealant 14 covers all of the convex ribs 9 provided in the frame area 200. In another embodiment, as shown in FIG. 2B, one or more convex ribs 9 are provided on a portion of the base substrate located in the frame area 200, and the encapsulation layer 13 covers all of the convex ribs 9 provided on the base substrate and located in the frame area 200. In other embodiments, as shown in FIG. 2C, a plurality of convex ribs 9 are provided on a portion of the base substrate located in the frame area 200, with a part of the convex ribs 9 being covered by the encapsulation layer 13 and another part of the convex ribs 9 being covered by the sealant 14. In the case that the convex ribs 9 are provided on a portion of the base substrate located in the display area 100, the encapsulation layer 13 covers all of the convex ribs 9 provided on the base substrate and located in the display area 100. As shown in FIG. 8, the encapsulation layer 13 may conformally cover the convex ribs 9. In addition, for example, in the case that the convex ribs 9 are provided on both the base substrate and the cover plate 12, orthographic projections of the convex ribs 9 provided on the base substrate on the cover plate 12 and the convex ribs 9 provided on the cover plate 12 are arranged at intervals. The display panel may be a foldable screen or a curved screen, which includes a bendable shaft. At least a portion of the convex rib 9 extends in a direction parallel to the bendable shaft. The bendable shaft is perpendicular to a bending direction or a folding direction. The bending direction or the folding direction may be an X direction in FIG. 16 or a Y direction in FIG. 17.

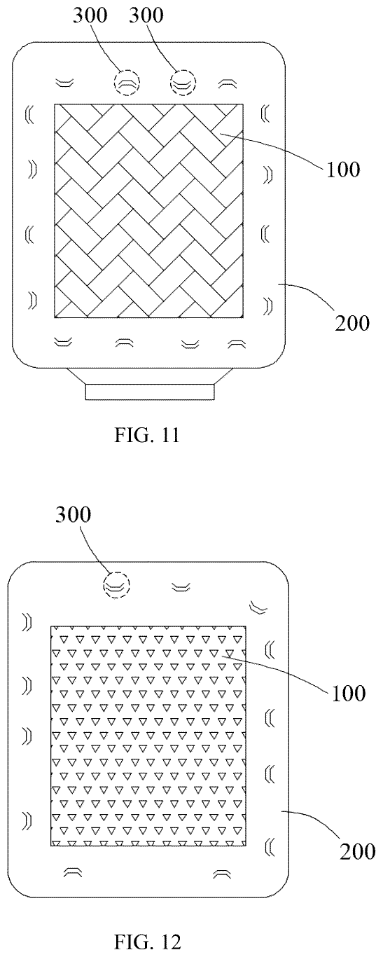

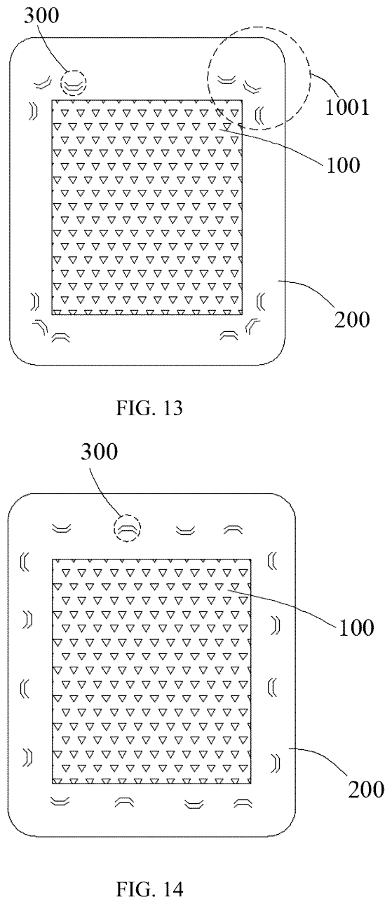

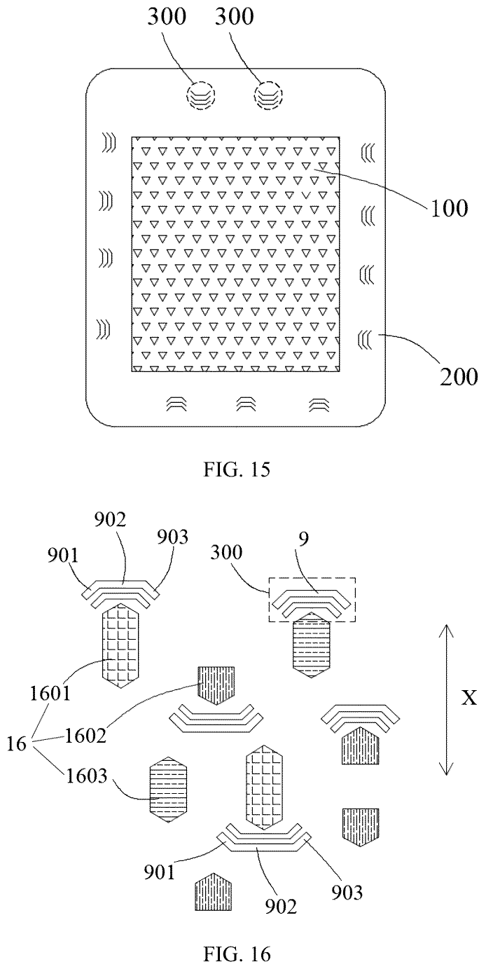

Further, as shown in FIG. 9 to FIG. 15, a convex rib group 300 is provided on at least one of the base substrate and the cover plate 12. The convex rib group 300 may include one, two, three, four, or more convex ribs 9. As shown in FIG. 9 and FIG. 12, a plurality of convex rib groups 300 may be located in the frame area 200 and provided on the base substrate or the cover plate 12, and the plurality of convex rib groups 300 are distributed at intervals, where the plurality of convex rib groups 300 may be distributed at intervals along a periphery of the display area 100, that is, the plurality of convex rib groups 300 may surround the display area 100. The plurality of convex rib groups 300 surrounding the display area 100 may be distributed evenly. However, the plurality of convex rib groups 300 surrounding the display area 100 may also be distributed unevenly. For example, as shown in FIG. 10 and FIG. 13, a density of the convex ribs 9 provided at a corner portion 1001 of the frame area 200 may be greater than a density of the convex ribs 9 provided at other portions of the frame area 200. For example, in the case of a rectangular or square display area 100, the frame area 200 is provided with four corner portions 1001. In addition, for example, in the case that the convex rib groups 300 are provided on both a portion of the base substrate located in the display area 100 and a portion of the cover plate 12 located in the display area 100, a density of the convex ribs 9 provided on the base substrate and located in the display area 100 is different from a density of the convex ribs 9 provided on the cover plate 12 and located in the display area 100. In particular, the density of the convex ribs 9 provided on the base substrate and located in the display area 100 is greater than the density of the convex ribs 9 provided on the cover plate 12 and located in the display area 100. Further, no convex ribs 9 may be provided on the cover plate 12 and located in the display area 100, so as not to affect light output from the display area 100.

In addition, as shown in FIG. 4, multiple convex ribs 9 in the convex rib group 300 may be distributed at intervals, and a trench is formed between adjacent two of the convex ribs 9. The trench may be a strip-shaped trench. As shown in FIG. 29, the convex rib group 300 in the present disclosure can stably resist a shearing action from the inside to the outside or from the outside to the inside, so as to prevent the encapsulation layer 13 or the sealant 14 from peeling. For the convex rib group 300 located in the frame area 200, a distance H (see FIG. 4) between two adjacent convex ribs 9 may be 8 μm to 15 μm, and further, the distance H between two adjacent convex ribs 9 may be greater than 10 μm, e.g., 12 μm, 13 μm, 14 μm, 15 μm, etc. For the convex rib group 300 located in the display area 100 and provided on the base substrate, a ratio of a distance H (see FIG. 4) between two adjacent convex ribs 9 to a thickness of the first inorganic encapsulation layer is equal to or greater than 2, and in particular, the distance H (see FIG. 4) between two adjacent convex ribs 9 is equal to or greater than 2 μm, e.g., 2 μm, 3 μm, 4 μm, 5 μm, 6 μm, etc. In addition, for the multiple convex ribs 9 in one convex rib group 300, different convex ribs 9 may have the same or different widths, and different convex ribs 9 may have the same or different lengths. In particular, a width D (see FIG. 4) of the convex rib 9 may be 3 μm to 6 μm, e.g., 3 μm, 4 μm, 5 μm, 6 μm, etc. A height of the convex rib 9 may be 1 μm to 3 μm, e.g., 1 μm, 2 μm, 3 μm, etc. A length of the convex rib 9 may be 4 μm to 30 μm, e.g., 4 μm, 8 μm, 25 μm, 30 μm, etc.

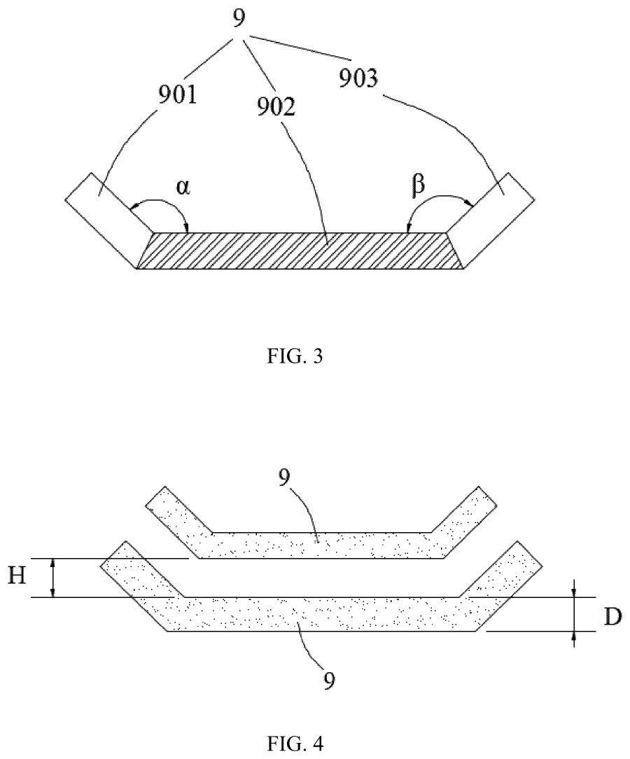

As shown in FIG. 3, at least some of the multiple convex ribs 9 may each include a plurality of rib segments connected sequentially in a direction parallel to the base 1. The rib segment may be a linear rib segment or a curved rib segment. The number of the rib segments may be two, three, four, or more. Different rib segments may have the same or different widths. In addition, the convex rib 9 may have an arcuate extension trajectory. For example, the plurality of rib segments may include at least a first rib segment 901, a second rib segment 902, and a third rib segment 903 connected sequentially. One end of the second rib segment 902 is connected to one end of the first rib segment 901, and the other end of the second rib segment 902 is connected to one end of the third rib segment 903. An end of the first rib segment 901 away from the second rib segment 902 and an end of the third rib segment 903 away from the second rib segment 902 may be located on the same side in a width direction of the second rib segment 902. However, the end of the first rib segment 901 away from the second rib segment 902 and the end of the third rib segment 903 away from the second rib segment 902 may be respectively located on both sides in the width direction of the second rib segment 902. A length of the first rib segment 901 may be equal to or different from a length of the third rib segment 903. A length of the second rib segment 902 may be greater than that of the first rib segment 901. However, the length of the second rib segment 902 may be equal to that of the first rib segment 901.

An angle is formed between adjacent two of the rib segments. In particular, an angle is formed between the first rib segment 901 and the second rib segment 902, and an angle is formed between the third rib segment 903 and the second rib segment 902. As shown in FIG. 3, the angle between the first rib segment 901 and the second rib segment 902 may be referred to as a first angle α, and the angle between the third rib segment 903 and the second rib segment 902 may be referred to as a second angle β. The first angle α may be equal to or different from the second angle β. The angle between two adjacent rib segments may be an obtuse angle or an acute angle, but is not limited thereto, and the angle between two adjacent rib segments may be a right angle. For example, the angle between two adjacent rib segments is an obtuse angle, such that stress concentration can be avoided. The obtuse angle may be 95° to 175°, e.g., 95°, 100°, 120°, 135°, 150°, 175°, etc.

The convex rib 9 may include a first convex rib and a second convex rib. For the first convex rib, an end of the first rib segment 901 away from the second rib segment 902 is located on a side of the second rib segment 902 facing the display area 100, and an end of the third rib segment 903 away from the second rib segment 902 is located on the side of the second rib segment 902 facing the display area 100. For the second convex rib, an end of the first rib segment 901 away from the second rib segment 902 is located on a side of the second rib segment 902 facing away from the display area 100, and an end of the third rib segment 903 away from the second rib segment 902 is located on the side of the second rib segment 902 facing away from the display area 100.

As shown in FIG. 9, the convex rib 9 provided on the base substrate and located in the frame area 200 may be the first convex rib; however, the convex rib 9 provided on the base substrate and located in the frame area 200 may be the second convex rib. As shown in FIG. 11, for example, in the case that multiple convex rib groups 300 are provided on the base substrate and are distributed at intervals along the periphery of the display area 100, among adjacent two of the convex rib groups 300, the convex ribs 9 in one convex rib group 300 are the first convex ribs, and the convex ribs 9 in the other convex rib group 300 are the second convex ribs. The convex rib 9 provided on the cover plate 12 and located in the frame area 200 may be the first convex rib. However, as shown in FIG. 12, the convex rib 9 provided on the cover plate 12 and located in the frame area 200 may be the second convex rib. As shown in FIG. 14, for example, in the case that multiple convex rib groups 300 are provided on the cover plate 12 and are distributed at intervals along the periphery of the display area 100, among adjacent two of the convex rib groups 300, the convex ribs 9 in one convex rib group 300 are the first convex ribs, and the convex ribs 9 in the other convex rib group 300 are the second convex ribs. The convex rib 9 provided on the base substrate and located in the display area 100 may be the first convex rib or the second convex rib. The convex rib 9 provided on the cover plate 12 and located in the display area 100 may be the first convex rib or the second convex rib. For example, in the case that multiple convex ribs 9 are provided on a portion of the base substrate located in the display area 100, a part of the multiple convex ribs 9 are the first convex ribs, and another part of the multiple convex ribs 9 are the second convex ribs. For example, in the case that multiple convex ribs 9 are provided on a portion of the cover plate 12 located in the display area 100, a part of the multiple convex ribs 9 are the first convex ribs, and another part of the multiple convex ribs 9 are the second convex ribs.

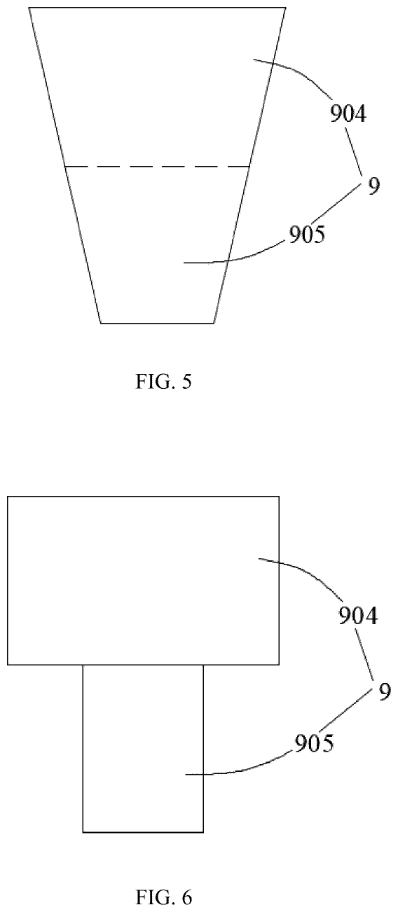

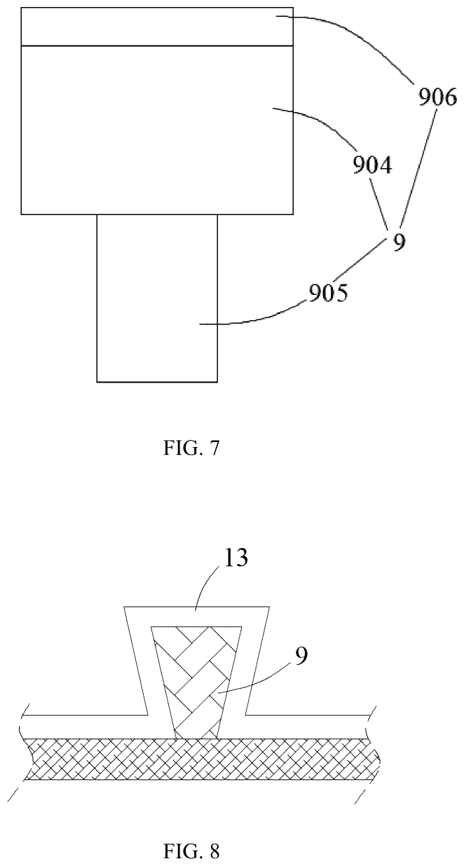

As shown in FIG. 5, FIG. 6, and FIG. 7, the convex rib 9 may include a first portion 904 and a second portion 905 in a thickness direction of the base 1. A size of the first portion 904 is greater than that of the second portion 905 in a width direction of the convex rib 9, that is, an orthographic projection of the second portion 905 on the base substrate is located within an area of an orthographic projection of the first portion 904 on the base substrate. In the case that the convex rib 9 is provided on the base substrate, the first portion 904 of the convex rib 9 is located on a side of the second portion 905 away from the base substrate. In the case that the convex rib 9 is provided on the cover plate 12, the first portion 904 of the convex rib 9 is located on a side of the second portion 905 away from the cover plate 12. It can be seen that, the convex rib 9 has a structure with a wide top and a narrow bottom, which can better engage the encapsulation structure, thereby improving adhesion of the encapsulation structure, and achieving a good engaging effect. When the display panel is squeezed in a vertical direction, objects are in contact with each other and compressed, often accompanied by shear, such that the objects, when squeezed in the vertical direction, are accompanied by shear deformation in a horizontal direction. In the case of the stronger adhesion of the encapsulation structure, the shear deformation in the horizontal direction can be restricted, thereby improving the anti-squeeze effect of the display panel. A relationship between the adhesion of the encapsulation structure and a vertical squeezing force that the encapsulation structure can withstand is shown in the table below.

| Adhesion (N) | Squeezing force (N) |
|---|---|
| 1.21 | 35 |
| 4.54 | 38 |
| 4.9 | 40 |
| 5.56 | 43 |
| 6 | 49 |

It can be seen from the above table that, as the adhesion of the encapsulation structure increases, the vertical squeezing force that the encapsulation structure can withstand increases.

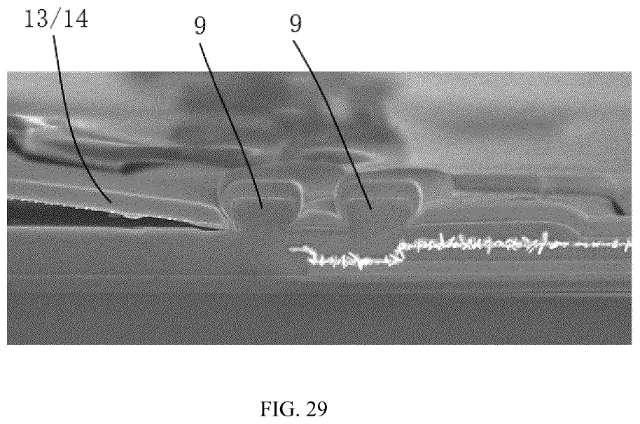

As shown in FIG. 6, the first portion 904 and the second portion 905 may be made of different materials, and an etch rate of a material of the first portion 904 is less than that of a material of the second portion 905. For the convex rib 9 provided on the base substrate and located in the frame area 200, in an embodiment, the second portion 905 of the convex rib 9 is made of an inorganic material and is provided on a surface of the second planarization layer 5 facing away from the base 1, and the pixel definition layer 7 covers the second portion 905, and an area of the pixel definition layer 7 covering the second portion 905 forms the first portion 904 of the convex rib 9. In another embodiment, the first portion 904 of the convex rib 9 is made of an inorganic material, and the second portion 905 of the convex rib 9 may be formed by a portion of the second planarization layer 5. As shown in FIG. 28, for the convex rib 9 provided on the base substrate and located in the display area 100, a plurality of strip-shaped grooves 701 distributed at intervals are provided in a surface of the pixel definition layer 7 facing the cover plate 12, a portion of the pixel definition layer 7 located between two adjacent strip-shaped grooves 701 forms the second portion 905 of the convex rib 9, and the first portion 904 of the convex rib 9 may include indium tin oxide. Further, as shown in FIG. 7, the convex rib 9 provided on the base substrate and located in the display area 100 may further include a third portion 906 formed by a portion of the cathode 63 of the light-emitting unit 6. In other embodiments of the present disclosure, as shown in FIG. 5, the first portion 904 and the second portion 905 may be made of the same material which includes a negative photoresist material.

For the convex rib group 300 provided in the display area 100, an orthographic projection of the convex rib group 300 on the base 1 may be located within an area of an orthographic projection of the pixel definition layer 7 on the base 1. That is, as shown in FIG. 1, an orthographic projection of the convex rib 9 provided in the display area 100 on the base 1 may be located within the area of the orthographic projection of the pixel definition layer 7 on the base 1. As shown in FIG. 16, multiple convex rib groups 300 may be provided in the display area 100. One convex rib group 300 may be provided on a periphery of one pixel opening 16. However, as shown in FIG. 24, multiple convex rib groups 300 may be provided on the periphery of one pixel opening 16, for example, two convex rib groups 300 may be provided on the periphery of one pixel opening 16, and the two convex rib groups 300 are located on opposite sides of the pixel opening 16 in a one-to-one correspondence. In other embodiments of the present disclosure, no convex rib groups 300 may be provided on the periphery of some pixel openings 16.

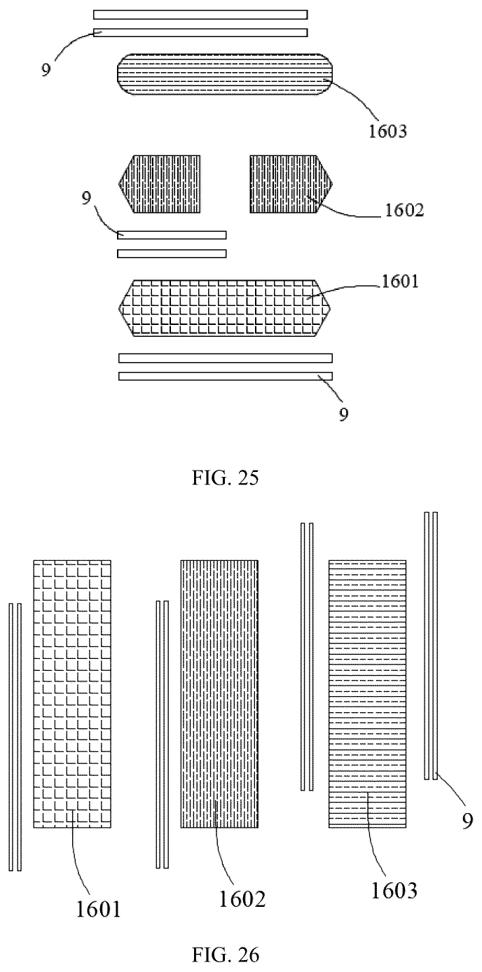

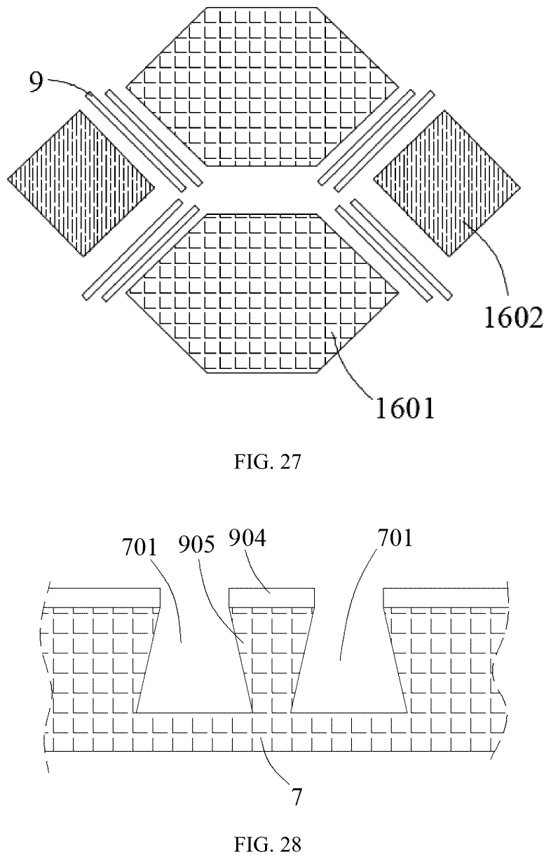

As shown in FIG. 16 to FIG. 18, for multiple convex ribs 9 provided in the display area 100, at least some of the rib segments of one convex rib 9 may be parallel to at least some of the rib segments of another convex rib 9. For example, in the case that the convex rib 9 includes the first rib segment 901, the second rib segment 902, and the third rib segment 903 connected sequentially, the second rib segment 902 of one convex rib 9 may be parallel to the second rib segment 902 of another convex rib 9. Further, the plurality of rib segments of one convex rib 9 may be parallel to the plurality of rib segments of another convex rib 9 in a one-to-one correspondence. In other embodiments of the present disclosure, as shown in FIG. 25 to FIG. 27, for multiple convex ribs 9 provided in the display area 100, one convex rib 9 is parallel to another convex rib 9.

As shown in FIG. 18, two convex ribs 9 of which the second rib segments 902 are parallel to each other may be in the same convex rib group 300. However, two convex ribs 9 of which the second rib segments 902 are parallel to each other may be in different convex rib groups 300. For example, in the case that two convex rib groups 300 are provided on the periphery of one pixel opening 16, and the two convex rib groups 300 are located on both sides of the pixel opening 16, the second rib segment 902 of the convex rib 9 in one convex rib group 300 is parallel to the second rib segment 902 of the convex rib 9 in the other convex rib group 300.

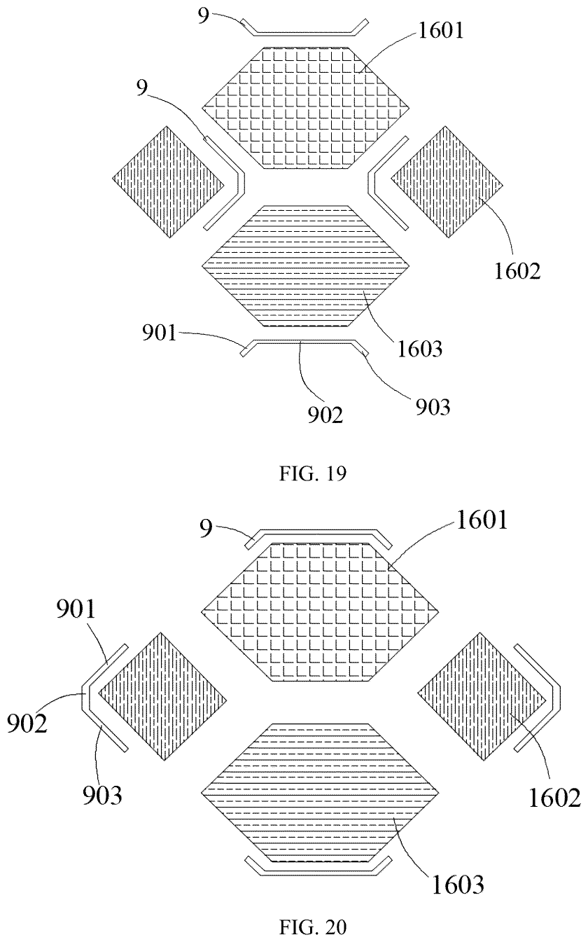

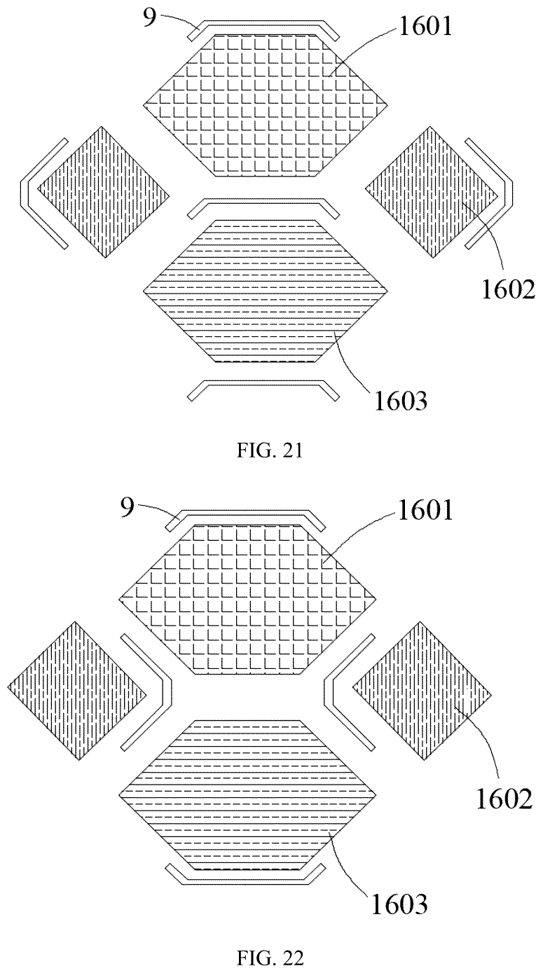

In addition, as shown in FIG. 19 to FIG. 22, for multiple convex ribs 9 provided in the display area 100, at least some of the rib segments of one convex rib 9 may be perpendicular to at least some of the rib segments of another convex rib 9. For example, in the case that the convex rib 9 includes the first rib segment 901, the second rib segment 902, and the third rib segment 903 connected sequentially, the second rib segment 902 of one convex rib 9 may be perpendicular to the second rib segment 902 of another convex rib 9. The two convex ribs 9 of which the second rib segments 902 are perpendicular to each other may be in different convex rib groups 300.

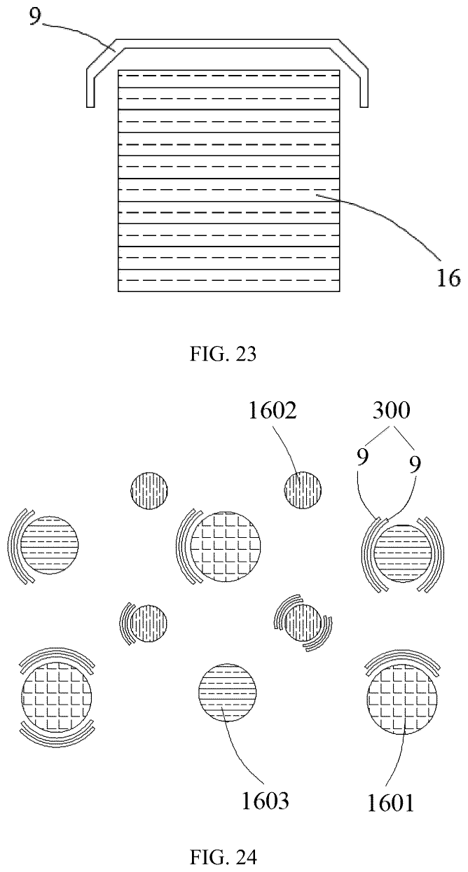

For example, in the case that the extension trajectory of the convex rib 9 is arcuate, the convex rib 9 may surround the pixel opening 16. As shown in FIG. 16, in the case of a polygonal pixel opening 16 as an example, the convex rib 9 may surround a vertex of the pixel opening 16. As shown in FIG. 23, in the case of a polygonal pixel opening 16 as an example, the convex rib 9 may surround two vertexes of the pixel opening 16. In addition, the extension trajectory of the convex rib 9 may be curved (see FIG. 24) or linear (see FIG. 25 to FIG. 27).

Embodiments of the present disclosure further provide a display apparatus. The display apparatus may include the display panel according to any one of the above embodiments. The display apparatus may be a mobile phone, a tablet computer, a TV, or the like. Since the display panel in the display apparatus according to the embodiment of the present disclosure is the same as the display panel according to the above embodiments of the display panel, they have the same beneficial effects, which will not be repeated herein.

The foregoing are merely preferred embodiments of the present invention, and are not intended to limit the present invention in any form. Although the present invention has been disclosed as above in the preferred embodiments, the present invention is not limited thereto. Any person skilled in the art may utilize the technical contents disclosed above to make some variations or modifications into equivalent embodiments with equivalent changes, without departing from the scope of the technical solution of the present invention. Any simple variations, equivalent changes and modifications made to the above embodiments based on the technical essence of the present invention without departing from the contents of the technical solution of the present invention shall fall within the scope of the technical solution of the present invention.

1. A display panel, comprising a display area and a frame area surrounding the display area, the display panel comprising:
a base substrate and a cover plate opposite to each other;
one or more convex ribs on at least one of the base substrate and the cover plate, wherein each convex rib of at least some of the convex ribs comprises a plurality of rib segments connected sequentially along an extension trajectory of the convex rib, and an angle is formed between adjacent two of the rib segments; and
an encapsulation structure between the base substrate and the cover plate and covering the convex ribs.

2. The display panel according to claim 1, wherein the plurality of rib segments comprise at least a first rib segment, a second rib segment, and a third rib segment connected sequentially, a first angle is formed between the first rib segment and the second rib segment, and a second angle is formed between the third rib segment and the second rib segment, and an end of the first rib segment away from the second rib segment and an end of the third rib segment away from the second rib segment are on a same side in a width direction of the second rib segment.

3. The display panel according to claim 1, wherein the angle formed between the adjacent two of the rib segments is an obtuse angle.

4. The display panel according to claim 1, wherein a plurality of convex rib groups are provided on at least one of the base substrate and the cover plate and are distributed at intervals, each convex rib group of the convex rib groups comprising one or more of the convex ribs.

5. The display panel according to claim 4, wherein multiple of the convex rib groups are in the frame area, and are distributed at intervals along a periphery of the display area.

6. The display panel according to claim 5, wherein the frame area is in a ring shape and comprises at least one corner portion, and a density of the convex ribs at the corner portion of the frame area is greater than that of the convex ribs at other portions of the frame area.

7. The display panel according to claim 4, wherein the plurality of rib segments comprise at least a first rib segment, a second rib segment, and a third rib segment connected sequentially, a first angle is formed between the first rib segment and the second rib segment, and a second angle is formed between the third rib segment and the second rib segment, and an end of the first rib segment away from the second rib segment and an end of the third rib segment away from the second rib segment are on a same side in a width direction of the second rib segment; and
the convex ribs comprise one or more first convex ribs and one or more second convex ribs, and for each of the first convex ribs, an end of the first rib segment away from the second rib segment is on a side of the second rib segment facing the display area, and for each of the second convex ribs, an end of the first rib segment away from the second rib segment is on a side of the second rib segment facing away from the display area.

8. The display panel according to claim 7, wherein multiple of the convex rib groups are provided on a portion of the base substrate located in the frame area and on a portion of the cover plate located in the frame area; and
the convex ribs in one or more convex rib groups provided on the base substrate and located in the frame area are the first convex ribs, and the convex ribs in one or more convex rib groups provided on the cover plate and located in the frame area are the second convex ribs, or the convex ribs in the one or more convex rib groups provided on the base substrate and located in the frame area are the second convex ribs, and the convex ribs in the one or more convex rib groups provided on the cover plate and located in the frame area are the first convex ribs.

9. The display panel according to claim 7, wherein multiple of the convex rib groups are provided on a portion of the base substrate located in the frame area, and are distributed at intervals along a periphery of the display area, and among adjacent two of the multiple of the convex rib groups, the convex ribs in one convex rib group are the first convex ribs, and the convex ribs in the other convex rib group are the second convex ribs; and/or
multiple of the convex rib groups are provided on a portion of the cover plate located in the frame area, and are distributed at intervals along the periphery of the display area, and among adjacent two of the multiple of the convex rib groups, the convex ribs in one convex rib group are the first convex ribs, and the convex ribs in the other convex rib group are the second convex ribs.

10. The display panel according to claim 1, wherein the encapsulation structure comprises a sealant provided in the frame area and bonded between the base substrate and the cover plate; and
wherein one of the convex ribs is provided in the frame area and is covered by the sealant, or wherein multiple of the convex ribs are provided in the frame area and are at least partially covered by the sealant.

11. The display panel according to claim 1, wherein the base substrate comprises a base and a light-emitting unit on the base, and the encapsulation structure comprises an encapsulation layer covering the light-emitting unit; and
wherein one of the convex ribs is provided on a portion of the base substrate located in the frame area and is covered by the encapsulation layer, or wherein multiple of the convex ribs are provided on the portion of the base substrate located in the frame area, with a part of the multiple of the convex ribs being covered by the encapsulation layer and another part of the multiple of the convex ribs being located outside the encapsulation layer; and the encapsulation structure further comprises a sealant which is bonded between the base substrate and the cover plate and covers the convex ribs located outside the encapsulation layer.

12. (canceled)

13. The display panel according to claim 1, wherein the encapsulation structure comprises an encapsulation layer; wherein the base substrate comprises a base, a light-emitting unit, and a barrier dam; wherein the light-emitting unit is provided on the base, and the encapsulation layer covers the light-emitting unit; wherein the barrier dam is provided on the base and located in the frame area, and the barrier dam is configured to block a portion of the encapsulation layer; and wherein one or more of the convex ribs are provided in the frame area on a side of the barrier dam away from the display area.

14. The display panel according to claim 1, wherein the convex rib comprises a first portion and a second portion in a thickness direction of the base substrate, and a size of the first portion is greater than that of the second portion in a width direction of the convex rib;
wherein in the case that the convex rib is provided on the base substrate, the first portion is located on a side of the second portion away from the base substrate; and
wherein in the case that the convex rib is provided on the cover plate, the first portion is located on a side of the second portion away from the cover plate.

15. (canceled)

16. The display panel according to claim 14- or 15, wherein one or more of the convex ribs are provided on a portion of the base substrate located in the frame area, and the base substrate comprises:
a base;
a driving transistor on the base;
a planarization layer on a side of the driving transistor facing away from the base, the second portions of the convex ribs in the frame area being on a surface of the planarization layer facing away from the base; and
a pixel definition layer covering the planarization layer and the second portions, an area of the pixel definition layer covering the second portions forming the first portions; or
wherein one or more of the convex ribs are provided on a portion of the base substrate located in the frame area, and the base substrate comprises:
a base;
a driving transistor on the base; and
a planarization layer on a side of the driving transistor facing away from the base, a portion of the planarization layer forming the second portions of the convex ribs in the frame area; or
wherein one or more of the convex ribs are provided on a portion of the base substrate located in the display area, and the base substrate comprises:
a base;
a pixel definition layer on a side of the base and with a pixel opening; and
a light-emitting unit in the pixel opening,
wherein a plurality of strip-shaped grooves are provided in a surface of the pixel definition layer facing the cover plate and are distributed at intervals, and a portion of the pixel definition layer located between adjacent two of the strip-shaped grooves forms the second portion.

17-18. (canceled)

19. The display panel according to claim 4, wherein one or more of the convex ribs are provided in the display area, and the base substrate comprises:
a base;
a pixel definition layer on a side of the base and with a pixel opening; and
a light-emitting unit in the pixel opening,
wherein orthographic projections of the convex ribs in the display area on the base are within an orthographic projection of the pixel definition layer on the base.

20. The display panel according to claim 19, wherein the extension trajectory of the convex rib is arcuate and surrounds at least one pixel opening; and
wherein the pixel opening is polygonal, and the extension trajectory of the convex rib surrounds a vertex of the pixel opening.

21-22. (canceled)

23. The display panel according to claim 19, wherein the plurality of rib segments comprise at least a first rib segment, a second rib segment, and a third rib segment connected sequentially, a first angle is formed between the first rib segment and the second rib segment, and a second angle is formed between the third rib segment and the second rib segment, and an end of the first rib segment away from the second rib segment and an end of the third rib segment away from the second rib segment are on a same side in a width direction of the second rib segment;
wherein multiple of the convex ribs are provided in the display area, with the second rib segment of one convex rib being parallel to the second rib segment of another convex rib; and multiple of the convex rib groups are provided in the display area, with two convex ribs of which the second rib segments are parallel to each other being in a same convex rib group, or two convex ribs of which the second rib segments are parallel to each other being in different convex rib groups; or
wherein multiple of the convex ribs are provided in the display area, with the second rib segment of one convex rib being perpendicular to the second rib segment of another convex rib, and two convex ribs of which the second rib segments are perpendicular to each other are in different convex rib groups.

24. (canceled)

25. The display panel according to claim 4, wherein the convex rib group comprises multiple of the convex ribs distributed at intervals, with a trench being formed between adjacent two of the multiple of the convex ribs.

26. (canceled)

27. The display panel according to claim 1, wherein the convex ribs are provided on the base substrate and the cover plate, and orthographic projections of the convex ribs on the base substrate on the cover plate and the convex ribs on the cover plate are arranged at intervals.

28. A display apparatus, comprising the display panel according to claim 1.
